(19) United States
(12) Patent Application Publication
(10) Pub. No.: US 2006/0153996 A1
(43) Pub. Date: Jul. 13, 2006

(54) Method and system for laser cladding

(76) Inventors: Jennifer M. Stanek, Clarkston, MI (US); Timothy L. Neal, Ortonville, MI (US); Chandran B. Santanam, Rochester Hills, MI (US); Ko-Jen Wu, Troy, MI (US)

Correspondence Address: GENERAL MOTORS CORPORATION;LEGAL STAFF, MAIL CODE 482-C23-B21, P O BOX 300, DETROIT, MI, 48265-3000, US

(21) Appl. No.: 11/035,163

(22) Filed: Jan. 13, 2005

(51) Int. Cl. C23C 14/30; C23C 16/52; B05C 11/00

(52) U.S. Cl. 427/596; 427/8; 118/712; 118/668

(57) ABSTRACT

A method and system for laser cladding includes determining a material thickness variation of a substrate, and varying laser intensity dependent on the determination of the material thickness variation of the substrate. The determination of the material thickness variation of the substrate includes calculating parameters indicative of a relative material thickness between a first target position and a second target position.

### BACKGROUND

The present disclosure relates generally to a method for laser cladding, and more particularly, to a method for manufacturing a valve seat using a laser cladding process.

In internal combustion engines, aluminum or aluminum alloys are frequently employed as materials for a number of the major engine castings such as the cylinder heads. When the cylinder heads are formed from aluminum or aluminum alloys, however, certain components of the cylinder head are formed from a dissimilar material so as to improve durability of the engine. For example, valve seats are provided where the valve face of an intake or exhaust valve engages the cylinder head body. Since the valve seat engages the intake or exhaust valve repeatedly and is subject to high temperature, the valve seat is formed from a harder material such as iron or ferrous iron alloys to extend the valve seat life.

Valve seat inserts for aluminum alloy engine heads have been used for some time to reinforce the valve seat areas that are continuously impacted by valves under high temperature and shock. These inserts are usually made of iron, or nickel-based powder-metal compacts to withstand the heat, stress and impact loading that is experienced in such applications. The inserts are pressed fit, or shrunk-fit into a pre-machined pocket of the head seat support. Although such inserts enhance wear resistance beyond that of the parent aluminum, they may limit engine combustion parameters by restricting heat flow from the valves into the cylinder head and ultimately to the cooling jacket. The increase in temperature can result from two aspects. First, there can be gaps as large as 50-150 micrometers between the insert and parent support metal of the cylinder head; such gaps prevent efficient heat evacuation away from the seat through the head during combustion, consequently increasing the temperature of the valves in contact with such seats. Secondly, inserts need to have a significant thickness to assure adequate rigidity during mechanical installation; such thickness contributes to thermal resistance, thus limiting thermal conduction from the valves. As a consequence, the engine operating parameters are often varied to prevent extreme temperatures from being experienced by the valves, such as by restricting the degree of spark advance and or compression ratio, thereby limiting the available horsepower and torque. In addition, the significant thickness of the valve seat insert limits the size of the valve, thereby limiting the available horsepower and torque.

Laser cladding has been used to reduce thermal and size barriers created by metal inserts. Laser cladding usually includes preplaced or simultaneously fed powders or wires of hard facing alloys disposed in the valve seat region by dilution with the aluminum base material of the cylinder head. Laser cladding can reduce the valve operating temperature by as much as 150° F. Furthermore, laser cladding allows larger diameter valve seats increasing engine air flow, and consequently, peak power.

In one known method, laser cladding is used to deposit copper based materials, such as a copper alloy powder, on an aluminum cylinder head to form a valve seat wherein the cladded material mixes with the parent material (i.e., dilution), replacing the conventional valve seat insert. However, laser cladding introduces a significant amount of heat into the seat supporting region which can significantly modify the metallurgy of the underlying aluminum alloy of the cylinder head. The quality of the deposit is determined by the power setting of the laser and feed rate selected for the cladding process, as well as the cooling of the materials after cladding is completed. For example, when a single power laser setting is used for cladding a valve seat, the result of the dilution between the two materials is not uniform. This non-uniformity is caused by the variable material thickness surrounding the valve seat due to the presence of cooling jackets, a spark plug hole, and a general varying configuration of the cylinder head proximate the valve seat. This variation in dilution is not desirable around the valve seat, which can lead to premature cracking.

More specifically, when heat from the laser is excessive, much of the aluminum alloy base metal is melted and the copper alloy powder is diluted so that the clad metal is changed to a hard and fragile alloy composition. When an amount of heat input from the laser is lacking, the copper alloy powder is not melted sufficiently into the aluminum base metal.

Accordingly, an improved method and system for manufacturing a valve seat using a laser cladding process which accounts for a variable material thickness of the cylinder head surrounding the valve seat is desired.

### BRIEF SUMMARY

Disclosed herein is a method for laser cladding. The method includes determining a material thickness variation of a substrate and varying laser intensity dependent on the determination of the material thickness variation of the substrate.

Also disclosed is a system for providing a cladding on a substrate. The system includes a means for determining a material thickness variation of a substrate, a means for providing calculated parameters of the material thickness variation of the substrate to a computer program, and a means for varying laser intensity dependent on the determination of the material thickness variation of the substrate.

Yet another system is further disclosed for providing a cladding on a substrate. The system includes a computer having modeling means to model the substrate in three dimensions (3-D) to determine a material thickness variation between first and second target positions of the substrate, the computer including processing means configured to predict a trend in the material thickness variation of the substrate.

The above-described and other features are exemplified by the following figures and detailed description.

### BRIEF DESCRIPTION OF THE DRAWINGS

Referring now to the figures, which are meant to be exemplary embodiments, and wherein like elements are numbered alike:

FIG. 1 is a perspective view of an engine cylinder head assembly with four combustion chambers, each chamber having an intake valve seat, an exhaust valve seat, and a spark plug hole therebetween;

FIG. 2 is a schematic diagram of a laser cladding system in operable communication with a cylinder head of FIG. 1 and a computer in accordance with an exemplary embodiment;

FIG. 3 is a flowchart of a method for laser cladding a substrate including the head assembly of FIG. 2 in accordance with an exemplary embodiment;

FIG. 4 is a perspective cross section view of the second combustion chamber of FIG. 1 depicted by a modeling system illustrating a variation of material thickness proximate the laser cladded valve seat;

FIG. 5 is a partial enlarged cross-section view of the combustion chamber of FIG. 4 depicted by the modeling system illustrating a radial slice for calculating a parameter corresponding therewith in accordance with an exemplary embodiment;

FIG. 6 is another modeling system view of the combustion chamber illustrating 72 radial slices or depicting a radial slice every five radial degrees of the valve seats for calculating a parameter thereof by the computer;

FIG. 7 is a graph plotting an area of a face of each radial slice in a series of contiguous radial slices against its radial position to illustrate a variation of material thickness trend of the cylinder head with respect to both the intake and exhaust valve seat areas; and

FIG. 8 is a graph plotting a volume of each radial slice in a series of contiguous radial slices against its radial position to illustrate a variation of material thickness trend of the cylinder head with respect to both the intake and exhaust valve seat areas.

### DETAILED DESCRIPTION OF THE PREFERRED EMBODIMENT

As used herein, the phrase “laser cladding process” means the laser powder or metal mixture deposition process in which material of a single layer or multiple layers is deposited on a substrate by melting the metal mixture and substrate by a laser to dilute the materials together. The phrase “clad” refers to the deposited layer on the substrate. The process of making clads is called “cladding” and synonymously “coating” when the thickness of the clad is small and the process is used to coat or dilute a surface of the substrate with another material.

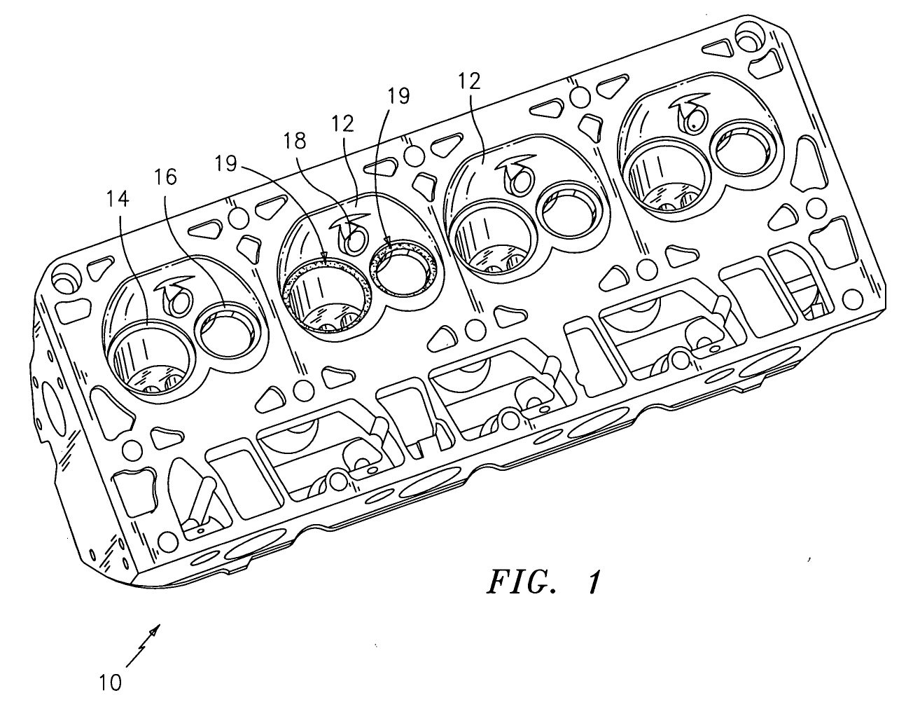

FIG. 1 illustrates an engine cylinder head assembly 10 with four combustion chambers 12 formed therewith. Each chamber 12 shows pre-machined pockets for the cladding deposition of an intake valve seat 14 and an exhaust valve seat 16 with an aperture 18 for threadably receiving a spark plug (not shown). Engine head assembly 10, as illustrated, is an aluminum-based head; however, other metal and metal alloy base materials are envisioned.

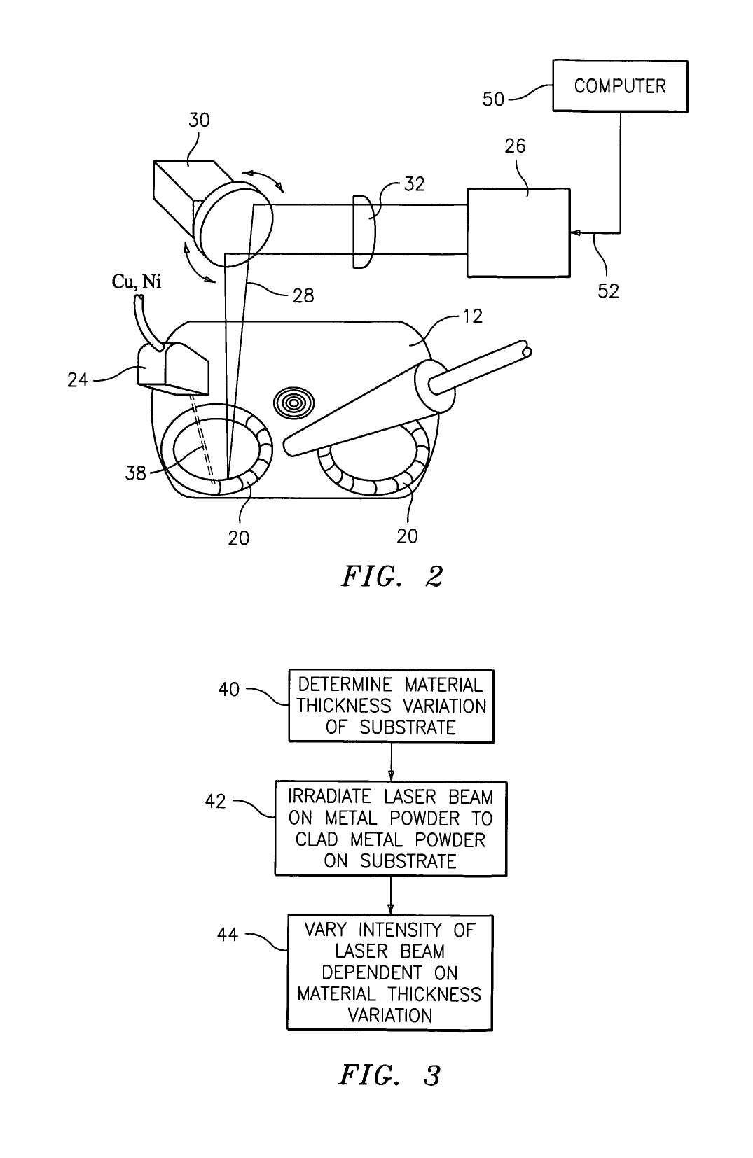

As illustrated in FIG. 2, according to an exemplary embodiment of the present disclosure, a laser beam having a high energy density is focused onto a specific area of metal to clad a powder metal mixture onto a parent material such that manufacture of a valve seat integral with the parent material (e.g., combustion chamber 12) is performed. That is, a laser beam is directed onto a valve seat target position 20 of the parent material while a controlled stream of the powder metal mixture is heated by the laser beam. The heat of the laser causes the base material and the powder metal mixture to fuse, forming a fused metallic bond. In an exemplary embodiment, the laser may be a continuous wave (CW) laser or a pulsed laser beam laser.

Still referring to FIG. 2, in an example process of performing laser cladding, a supply unit 24 is used for storing the powder metal mixture and supplying the same to the valve seat target position 20, and a nozzle (not shown) for supplying a shield gas to the powder metal mixture is injected onto the valve seat target position. Also used in the process are a laser beam supply source 26 for generating a laser beam 28, and a laser beam oscillator 30 that uses a lens 32 to focus the laser beam 28 emitted from the laser beam supply source 26 onto the powder metal mixture supplied to the valve seat target position 20 generally indicated at 38.

In general and referring to FIGS. 1 and 2, a method for manufacturing a valve seat includes pre-machining a “pocket” in the cylinder head material or metal substrate (e.g., combustion chamber 12), forming the valve seat target position 20 on an area of the head material corresponding to where the valve seats will be formed, removing an oxidation film formed on the fabricated valve seat target position 20, and injecting the powder metal mixture 38 onto the valve seat target position 20, and directing the laser beam 28 onto the powder metal mixture. While pre-machining the pocket in the casting is described as a source for the structure on which the valve seat target position is formed, persons of ordinary skill in the art will appreciate that other known processes may be employed to provide a suitable structure or substrate.

Referring now to FIG. 3, a method for manufacturing a valve seat in accordance with an exemplary embodiment of the present disclosure further includes determining a material thickness variation of the substrate proximate an area to be laser cladded at block 40. At block 42, a laser beam is irradiated on a metal mixture to clad the metal mixture on the substrate. At block 44 an intensity of the laser beam is varied dependent on the determination of the material thickness variation of the substrate at block 42. In this manner, the determination of the material thickness variation of the substrate proximate the target position is used to adjust laser intensity providing uniform dilution between the metal mixture and the substrate at the target position. More specifically, the laser is adjusted to vary the laser intensity according to a material thickness proximate an instant weld location corresponding to the target position.

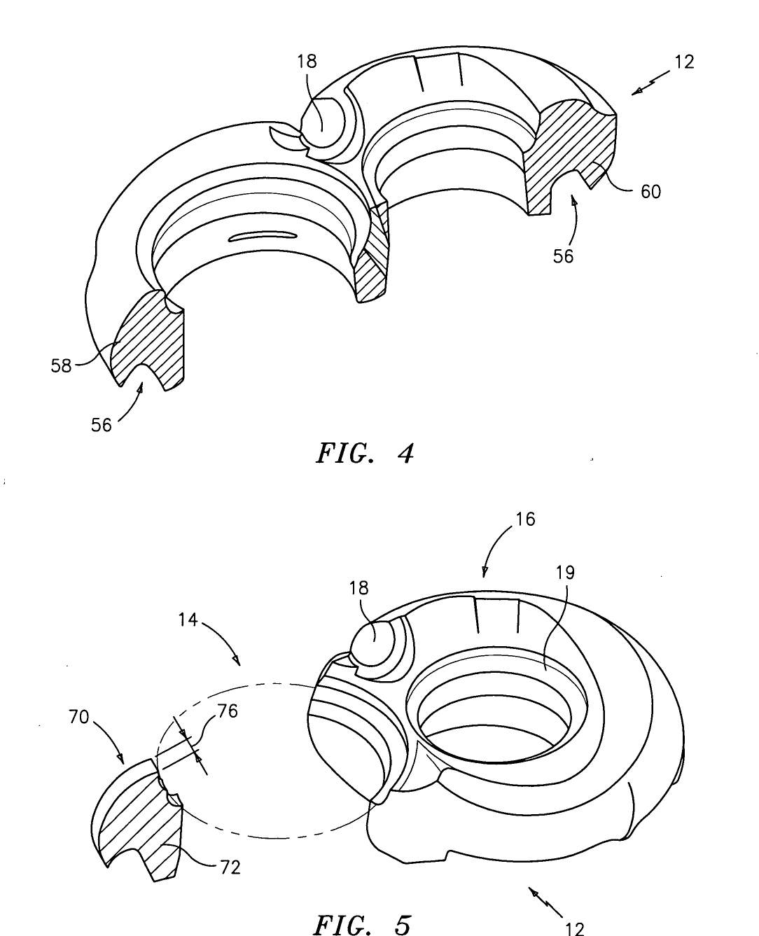

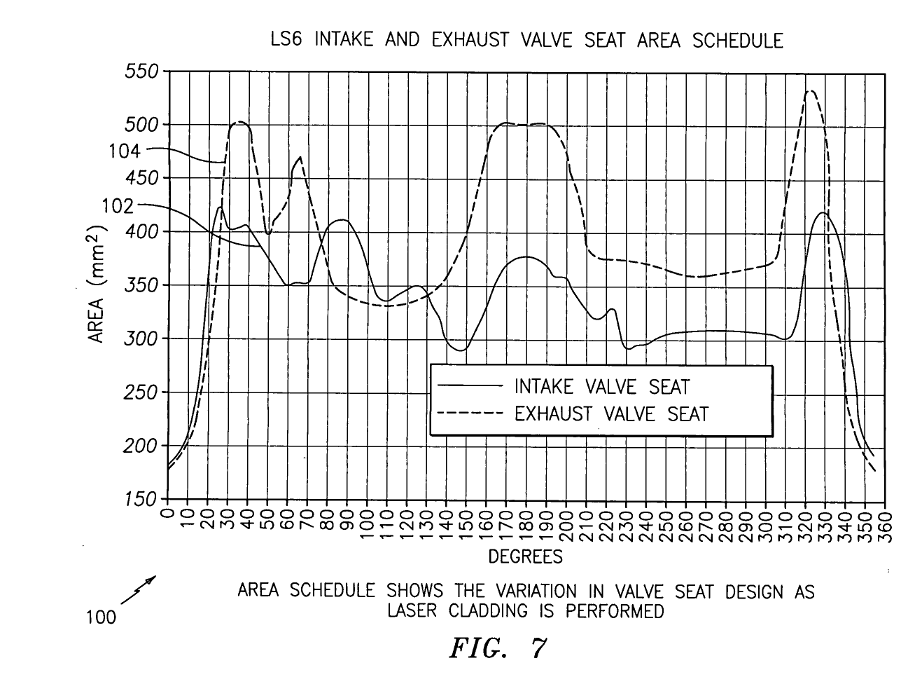

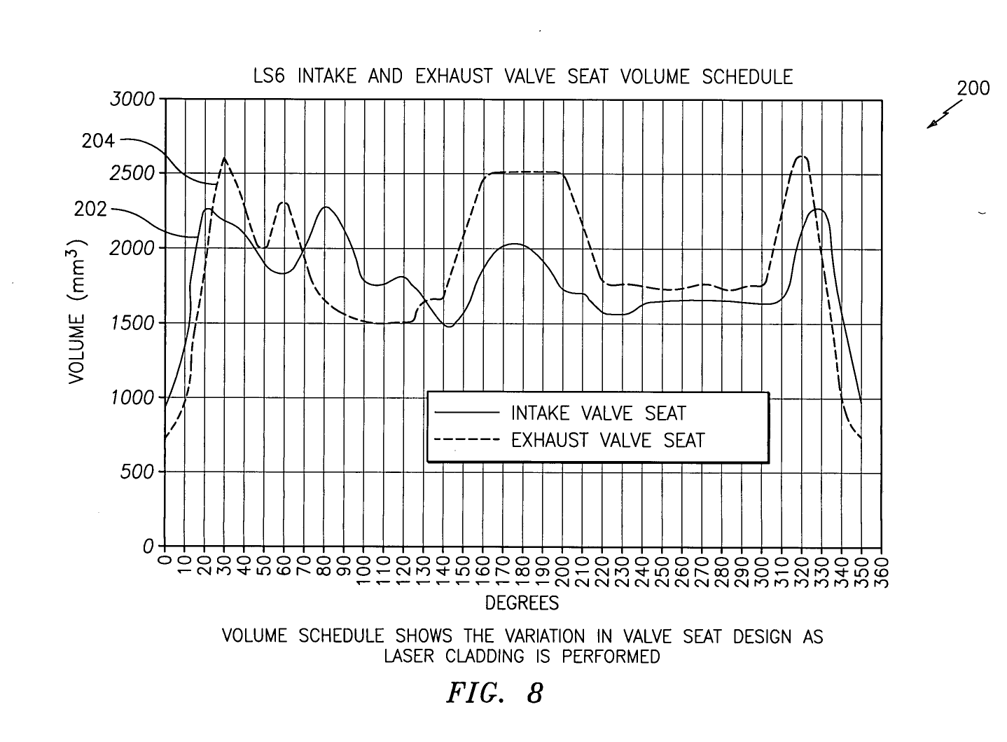

More specifically with reference to FIG. 4, a computer 50 (FIG. 2) in operable communication with laser or laser beam supply source 26 includes a modeling means to model head 12 in three dimensions (3-D) to determine a material thickness variation of the cylinder head 12 proximate each valve seat 14 and 16. The modeling means includes a computer-aided design system including a description of the article to be fabricated. In an exemplary embodiment, the modeling means includes CAD/CAM software configured to determine the material thickness variations in areas of head 12 to be irradiated. The computer 50 includes processing means configured to predict a trend in the material thickness variation of the substrate as discussed more fully below with respect to FIGS. 7 and 8. The computer 50 is interfaced to the laser 26 shown with line 52 in FIG. 2 to vary an intensity of the laser beam dependent on the determination of the material thickness variation of the substrate. Computer 50 may include a controller (not shown) for such an interface with laser 26. Further, the controller may include circuitry for adjusting the laser.

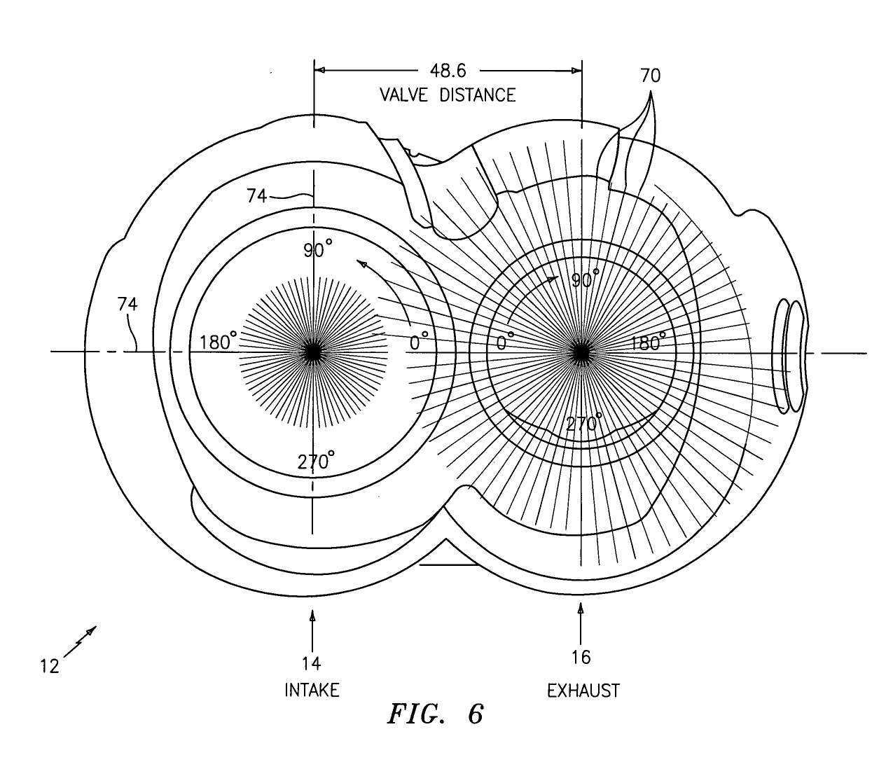

FIG. 4 illustrates that a material thickness of radial sections or slices about each pre-machined valve seat area 14 and 16 varies due to the presence of spark plug hole 18 and cooling jackets 56, as well as a general configuration of combustion chamber 12. For example, a cross section area at a first area 58 proximate valve seat 14 is different than a cross section area at a second area 60 proximate valve seat 16. FIG. 5 illustrates a radial slice 70 of intake valve seat area 14. It will be recognized by one skilled in the pertinent art that radial slice 70 includes a cross section face area indicated at 72 and a corresponding volume quantity proportional to the area 72, if radial slices or sections have substantially the same thickness 76.

Referring now to FIG. 6, a 3D image of both pre-machined intake and exhaust valve seat 14 and 16 of combustion chamber 12 is illustrated. In an exemplary embodiment, computer 50 includes CAD/CAM software configured to section each valve seat 14 and 16 into radial sections 70 and designates each with a radial position 74, as illustrated in FIG. 5. It will be recognized that radial section 70 shown in FIG. 5 corresponds to a radial position of about 180 radial degrees illustrated in FIG. 6 with respect to pre-machined intake valve seat 14. More specifically, the CAD/CAM software or other modeling means sections each valve seat 14 and 16 into radial sections to predict a trend of material thickness variation surrounding each valve seat 14 and 16. In this manner, computer 50 can calculate a parameter for each of the radial sections 70 that is reflective of a laser power intensity that should be applied to each radial section 70 to provide uniform dilution between the clad and base material. FIG. 6 illustrates that radial sections are taken every five radial degrees, and thus, illustrates 72 sections for each valve seat 14, 16 that are calculated to provide a trend in material thickness variation in a series of contiguous radial sections 70 defining each valve seat 14 and 16 (i.e., 360 radial degrees/5 radial degree sections=72 radial sections). It will be recognized by one skilled in the pertinent art that each valve seat 14 and 16 may be sectioned in other ways including sections having a specific thickness, for example. In this case, it is envisioned that sections 70 would be about 8 mm to about 15 mm thick.

In one example referring to FIGS. 6 and 7, a plot of a face area 72 against a radial position 74 of contiguous radial sections 70 for each valve seat 14, 16 is illustrated at 100. A schedule of face area corresponding to varying thickness of the intake valve seat 14 is indicated with solid line 102 while that for exhaust valve seat 16 is indicated with dashed line 104. It will be noted that the thinner sections of each valve seat occur proximate 0 and 360 degrees corresponding to a location where a distance between pre-machined valve seats 14 and 16 is most minimal. It will be further noted that proximate a radial position of 180 radial degrees, each pre-machined valve seat face area is at its maximum except at about 30 and 330 radial degrees corresponding with material build up of cylinder head 12 as more space between valve seats 14 and 16 is available.

With the information reflected in FIG. 7 with respect to the calculated face areas 72 of a series of contiguous radial sections 70, a trend of varying material thickness about each pre-machined valve seat 14, 16 is reflected. Thus, it becomes possible to adjust laser intensity with this information by increasing laser intensity at radial sections 70 having increased face areas 72 corresponding to thicker regions while reducing laser intensity at radial sections 70 having decreased face areas 72 corresponding to thinner regions. In this manner, a uniform dilution between both materials will result, thus improving strength and durability of a laser cladded valve seat.

In another example referring to FIGS. 6 and 8, a plot of a volume against a radial position of contiguous radial sections 70 for each pre-machined valve seat 14, 16 is illustrated at 200. A schedule of volume corresponding to varying thickness of the pre-machined intake valve seat 14 is indicated with solid line 202 while that for exhaust valve seat 16 is indicated with dashed line 204. Again, as in the plot of face areas 72, it will be noted that the thinner sections of each valve seat occur proximate 0 and 360 degrees corresponding to a location where a distance between valve seats 14 and 16 is most minimal. It will be further noted that proximate a radial position of 180 radial degrees, each valve seat face area is at it maximum except at about 30 and 330 radial degrees corresponding with material build up of combustion chamber 12 as more space between pre-machined valve seats 14 and 16 become available because of a separation therebetween.

With the information reflected in FIG. 8 with respect to the calculated volumes of a series of contiguous radial sections 70, a trend of varying material thickness about each pre-machined valve seat 14, 16 is reflected. Thus, it becomes possible to adjust laser intensity with this information by increasing laser intensity at radial sections 70 having increased volumes corresponding to thicker regions while reducing laser intensity at radial sections 70 having decreased volumes corresponding to thinner regions. In this manner, a uniform dilution between both materials will result, thus improving strength and durability of a laser cladded valve seat.

Referring now to FIGS. 7 and 8, it will be noted that a calculated parameter of either face area 72 or volume for each radial section 70 provides a similar trend in data to determine a varying material thickness with respect to each pre-machined valve seat 14, 16. These parameters can also determine an ultimate starting point for the laser beam 28 to begin the process with reference to FIGS. 6-8. More specifically, in an exemplary embodiment, a power intensity of laser beam 28 may begin low at the 0 radial degree position intermediate pre-machined valve seat pockets 14 and 16. The power intensity of laser beam 28 then may elevate in power as the laser beam traverses around intake valve seat 14 maximizing at about 30, 180, and 330 radial degree positions before crossing the 360 degree position corresponding with the 0 degree position. Due to the two valve configurations, laser beam 28 may traverse cylinder head in a figure “8” pattern as laser beam 28 finishes the cladding process for exhaust valve seat 16 in similar fashion with respect to laser power intensity at the respective radial positions described above with respect to pre-machined intake valve seat pocket 14.

By using such a laser cladding process to clad the valve seat target position 20, the fabrication of the valve seats is made relatively easy. For example, the diameter of the valve seat and that of the valve contacting the valve seat may be more freely varied during design as a result of the improvement in valve seat resistance to wear. Also, by reducing the temperature of the valve seat, the compression ratio can be increased and fuel. consumption reduced. Further, manufacturing costs are reduced by improving productivity and reducing premature cracking during durability tests by elimination of variation in dilution.

In the method and system for manufacturing valve seats using a laser cladding process of the present disclosure described above, the high energy density property of laser beams is applied to the manufacture of valve seats such that the fusing strength between the parent material and the clad layer is increased, and the resulting valve seats are able to withstand high temperatures and are highly wear-resistant, thereby enhancing the overall life-span of the engine. It will be recognized however, that although the exemplary embodiments for laser cladding have been described with reference to valve seats of a cylinder head, the above described method and system for laser cladding can be used for laser cladding a metal mixture with any substrate suitable to the desired end purpose.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to a particular embodiment disclosed as the best mode contemplated for carrying out this invention, but that the invention will include all embodiments falling within the scope of the appended claims.

What is claimed is:

1. A method for laser cladding, the method comprising:
determining a material thickness variation of a substrate; and
varying laser intensity during laser cladding dependent on the determination of the material thickness variation of the substrate.

2. The method of claim 1, wherein the determination of the material thickness variation of the substrate includes calculating parameters indicative of a relative material thickness between a first target position and a second target position.

3. The method of claim 2, wherein the calculated parameters are used to adjust laser intensity providing uniform dilution between the metal mixture and the substrate at the first and second target positions.

4. The method of claim 3, wherein the calculated parameters are used to determine at least one of a starting point and a stopping point on the substrate to initiate and finish the cladding process, respectively.

5. The method of claim 2, wherein the calculating parameters include at least one of calculating a surface area and a volume corresponding to each of the first and second target positions.

6. The method of claim 5, wherein the calculating the surface area and the volume corresponding to each of the first and second target positions include radial pieces defining at least a portion of the substrate corresponding with an area to be cladded.

7. The method of claim 6, wherein at least one of the area and volume of each radial piece is plotted on a linear graph against its radial position.

8. The method of claim 7, wherein a trend of material thickness variation can be predicted with respect to areas to be laser cladded.

9. The method of claim 6, wherein each radial piece includes a radial section corresponding to about 5 radial degrees.

10. The method of claim 6, wherein each radial piece includes a radial section having a sectioned width of between about 8 mm to about 15 mm.

11. The method of claim 1, further comprising:
using CAD/CAM software to determine the material thickness variations in areas of the substrate to be irradiated to assist in adjusting an intensity of the laser beam to accommodate variable material thickness corresponding to the areas of the substrate to be irradiated.

12. The method of claim 2, wherein the substrate is an engine cylinder head and the first and second target positions define an area to be irradiated including a pre-machined pocket for at least one valve seat associated with the engine cylinder head.

13. The method of claim 12, wherein the valve seat includes one of two and multiple valve seats per combustion chamber, each chamber including an intake valve seat adjacent to one of an exhaust valve seat and an intake valve seat.

14. The method of claim 12, further comprising:
initiating irradiation of the laser at a point intermediate any two adjacent valve seats facilitating a FIG. 8 motion of the laser beam during the laser cladding process.

15. The method of claim 12, wherein the engine cylinder head is fabricated of aluminum or an aluminum alloy.

16. The method of claim 12, wherein the calculating parameters include at least one of calculating a surface area and a volume corresponding to each of the first and second target positions.

17. The method of claim 16, wherein the calculating the surface area and the volume corresponding to each of the first and second target positions include radial pieces defining at least a portion of the head corresponding with an area to be cladded.

18. The method of claim 17, wherein at least one of the area and volume of each radial piece is plotted on a linear graph against its radial position.

19. The method of claim 18, wherein a trend of material thickness variation can be predicted with respect to areas to be laser cladded.

20. The method of claim 17, wherein each radial piece includes a radial section corresponding to one of about 5 radial degrees and a sectioned width of between about 8 mm to about 15 mm.

21. A system for providing a cladding on a substrate comprising:
a means for determining a material thickness variation of a substrate;
a means for providing calculated parameters of the material thickness variation of the substrate to a computer program; and
a means for varying laser intensity dependent on the determination of the material thickness variation of the substrate.

22. A system for providing a cladding on a substrate comprising:
a computer having modeling means to model the substrate in three dimensions (3-D) to determine a material thickness variation between first and second target positions of the substrate, the computer including processing means configured to predict a trend in the material thickness variation of the substrate.
